(19) United States
(12) Patent Application Publication
(10) Pub. No.: US 2025/0102449 A1
(43) Pub. Date: Mar. 27, 2025

(54) RADIATION DETECTOR ARRAY WITH STAGGERED DETECTOR MODULES

(71) Applicant: RedLen Technologies, Inc., Saanichton (CA)

(72) Inventors: Michael K. JACKSON, Victoria (CA); Devon RICHTSMEIER, Victoria (CA); Krzysztof INIEWSKI, Port Moody (CA)

(21) Appl. No.: 18/823,111

(22) Filed: Sep. 3, 2024

Related U.S. Application Data
(60) Provisional application No. 63/585,007, filed on Sep. 25, 2023.

(51) Int. Cl. G01N 23/046; H01L 27/146

(52) U.S. Cl. CPC G01N 23/046; H10F 39/8023

(57) ABSTRACT

A detector array includes a plurality of radiation sensors each including a two dimensional array of pixel detectors. The plurality of radiation sensors are arranged in rows of pixel detectors extending in a first direction and columns of pixel detectors extending in a second direction, and at least some of the plurality of the radiation sensors that are located adjacent to one another along the first direction are offset from one another along the second direction by an integer number of pixel detectors.

### FIELD

The present disclosure relates generally to radiation detectors, and more specifically to radiation detector arrays having staggered detector modules.

### BACKGROUND

Room temperature pixelated radiation detectors made of semiconductors, such as cadmium zinc telluride (Cd₁₋ₓZnₓTe where 0<x<1, or “CZT”), are gaining popularity for use in medical and non-medical imaging. These applications use the high energy resolution and sensitivity of the radiation detectors.

### SUMMARY

According to an aspect of the present disclosure, a detector array includes a plurality of radiation sensors each including a two dimensional array of pixel detectors. The plurality of radiation sensors are arranged in rows of pixel detectors extending in a first direction and columns of pixel detectors extending in a second direction, and at least some of the plurality of the radiation sensors that are located adjacent to one another along the first direction are offset from one another along the second direction by an integer number of pixel detectors.

Further embodiments include X-ray imaging systems including a radiation source configured to emit an X-ray beam, and an above-described detector module that is configured to receive the X-ray beam from the radiation source through an intervening space configured to contain an object therein.

### BRIEF DESCRIPTION OF THE DRAWINGS

FIG. 1A is a functional block diagram of an X-ray imaging system in accordance with various embodiments of the present disclosure.

FIG. 1B is a schematically illustration of an application specific integrated circuit (ASIC) configured to count X-ray photons detected in each pixel detector within a set of energy bins according to various embodiments of the present disclosure.

FIG. 2A is a rear perspective view of a detector array for a computed tomography (CT) X-ray imaging system according to various embodiments of the present disclosure.

FIG. 2B is a perspective view of a CT X-ray imaging system illustrating the orientation of the detector array with respect to an X-ray source and a patient being imaged according to various embodiments of the present disclosure.

FIG. 3A is a vertical cross-sectional view of a radiation detector unit according to one embodiment of the present disclosure.

FIG. 3B is a side view of an alternative configuration of a radiation detector unit according to various embodiments of the present disclosure.

FIG. 4 is a perspective view of a detector module including a plurality of radiation detector units mounted to a frame bar according to various embodiments of the present disclosure.

FIG. 5 is a top view of a detector array including a plurality of detector modules according to comparative embodiments of the present disclosure.

FIG. 6 is a top view of a detector array including a plurality of detector modules that are staggered along the Z-axis direction according to various embodiments of the present disclosure.

FIG. 7 is a top view of an alterative configuration of a detector array including a plurality of detector modules that are staggered along the Z-axis direction according to various embodiments of the present disclosure.

### DETAILED DESCRIPTION

Embodiments of the present disclosure provide detector arrays for ionizing radiation, the various aspects of which are described herein with reference to the drawings.

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims. Any reference to claim elements in the singular, for example, using the articles “a,” “an,” or “the” is not to be construed as limiting the element to the singular. The terms “example,” “exemplary,” or any term of the like are used herein to mean serving as an example, instance, or illustration. Any implementation described herein as an “example” is not necessarily to be construed as preferred or advantageous over another implementation. The drawings are not drawn to scale. Multiple instances of an element may be duplicated where a single instance of the element is illustrated, unless absence of duplication of elements is expressly described or clearly indicated otherwise.

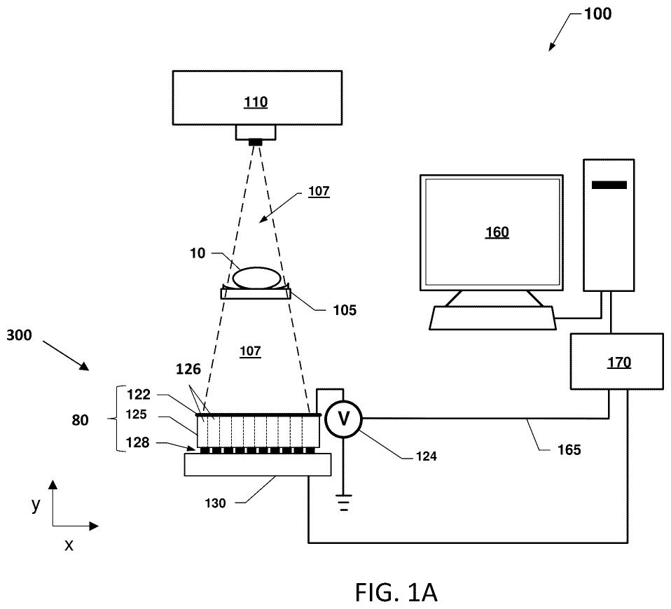

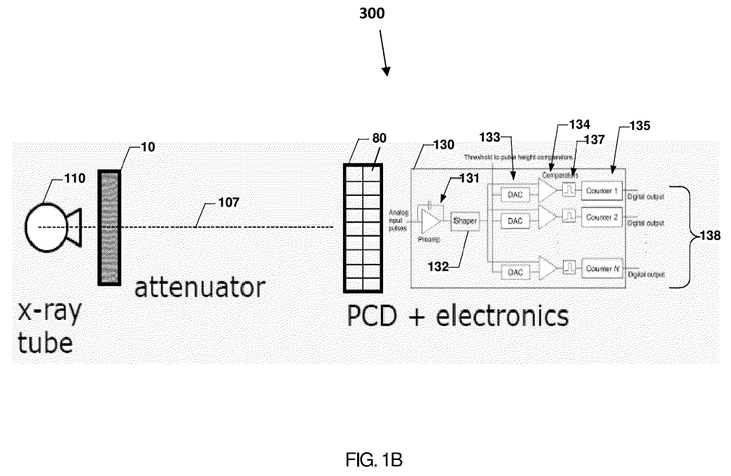

FIG. 1A is a functional block diagram of an X-ray imaging system 100 in accordance with various embodiments. The X-ray imaging system 100 may include an X-ray source 110 (i.e., a source of ionizing radiation), and an energy discriminating photon counting radiation detector array 300. The X-ray imaging system 100 may additionally include a patient support structure 105, such as a table or frame, which may rest on the floor and may support an object 10 to be scanned. In some embodiments, the object 10 may be a biologic subject (i.e., a human or animal patient). The support structure 105 may be stationary (i.e., non-moving) or may be configured to move relative to other elements of the X-ray imaging system 100, such as the X-ray source. For example, in a non-destructive testing imaging system, the support structure 105 may comprise a moving belt or web which supports the object 10. The object 10 may laterally translated by the moving belt or web past a stationary X-ray source 110, while the stationary detector array 300 is located under the belt or web. The object 10 may comprise food, baggage, manufactured products, or any other object that is subject to non-destructive testing to determine the object's composition (e.g., whether the food contains impurities), contents (e.g., contents of baggage), and/or defects (e.g., defects in manufactured products).

The X-ray source 110 may be mounted to a gantry (e.g., for CT imaging) or another support, and may move or remain stationary (e.g., in non-destructive testing) relative to the object 10. The X-ray source 110 is configured to deliver ionizing radiation to the radiation detector array 300 by emitting an X-ray beam 107 toward the object 10 and the radiation detector array 300. After the X-ray beam 107 is attenuated by the object 10, the beam of radiation 107 is received by the radiation detector array 300.

The radiation detector array 300 may include one or more radiation sensors 80 coupled to detector read-out circuitry 130. Each radiation sensor 80 may be controlled by a high voltage bias power supply 124 that selectively creates an electric field between an anode 128 and cathode 122 pair coupled thereto. In one embodiment, each radiation sensor 80 includes a plurality of anodes 128 (e.g., one anode per pixel) and one common cathode 122 electrically connected to the power supply 124 and facing the X-ray source 110. Each radiation sensor 80 may include a detector material 125, such as a semiconductor material disposed between the anode 128 and cathode 122 and thus configured to be exposed to the electrical field therebetween. The semiconductor material may comprise any suitable semiconductor material for detecting X-ray radiation disposed between the anode 128 and cathode 122 and thus configured to be exposed to the electrical field therebetween. In various embodiments, the semiconductor material of the radiation sensor(s) 80 may comprise a II-VI semiconductor material, such as cadmium telluride, cadmium zinc telluride (i.e., CdZnTe or “CZT”), cadmium selenide telluride, and cadmium zinc selenide telluride. Other suitable semiconductor materials are within the contemplated scope of disclosure.

The detector read-out circuitry may include one or more application specific integrated circuits (ASICs) 130. Each ASIC 130 may be coupled to one or more radiation sensors 80 and may receive signals (e.g., charge or current) from the anodes 128 of the radiation sensor(s) 80. Each ASIC 130 may be configured to provide data to and by controlled by a control unit 170. Each of the radiation sensors 80 may be segmented or configured into a large number of small “pixel” detectors 126. In various embodiments, the pixel detectors 126 of the radiation sensors 80 and the ASIC(s) 130 are configured to output data that includes counts of photons detected in each pixel detector 126 in each of a number of energy bins. Thus, radiation detector arrays 300 of various embodiments may provide both two-dimensional detection information regarding where photons were detected, thereby providing image information, and measurements of the energy of the detected X-ray photons. A radiation detector array 300 that is capable of measuring the energy of the X-ray photons impinging on the array 300 may be referred to as an energy-discriminating radiation detector array 300.

The control unit 170 may be configured to synchronize the X-ray source 110, the read-out ASIC(s) 130, and the high voltage bias power supply 124. The control unit 170 may be coupled to and operated from a computing device 160. Alternatively, the computing device 160 and the control unit 170 may be integrated together as one device.

In some embodiments, the X-ray imaging system 100 may be a computed tomography (CT) imaging system. The CT imaging system 100 may include a gantry (not shown in FIG. 1A), which may include a moving part, such as a circular, rotating frame with the X-ray source 110 mounted on one side and the radiation detector array 300 mounted on the other side. The radiation detector array 300 may have a curved shape along its long axis (i.e., the x-axis direction in FIG. 1A) such that each of the pixel detectors 126 along the length of the radiation detector may face towards the focal spot of the X-ray source 110. The gantry may also include a stationary (i.e., non-moving) part, such as a support, legs, mounting frame, etc., which rests on the floor and supports the moving part. The X-ray source 110 may emit a fan-shaped or cone-shaped X-ray beam 107 as the X-ray source 110 and the radiation detector array 300 rotate on the moving part of the gantry around the object 10 to be scanned. After the X-ray beam 107 is attenuated by the object 10, the X-ray beam 107 is received by the radiation detector array 300. The curved shape of the radiation detector array 300 may allow the CT imaging system 100 to most effectively reject radiation scattered by the object 10.

For each complete rotation of the X-ray source 110 and the radiation detector array 300 around the object 10, one cross-sectional slice of the object 10 may be acquired. As the X-ray source 110 and the radiation detector array 300 continue to rotate, the radiation detector array 300 may take numerous snapshots called “views”. Typically, about 1,000 profiles are taken in one rotation of the X-ray source 110 and the radiation detector array 300. The X-ray source 110 and the detector array 300 may slowly move relative to the object (e.g., patient) 10 along a horizontal direction (i.e., into and out of the page in FIG. 1A) so that the detector array 300 may capture incremental cross-sectional profiles over a region of interest (ROI) of the object 10, which may include the entire object 10. The data acquired by the radiation sensor(s) 80 and output by the read-out ASIC(s) 130 may be passed along to the computing device 160 that may be located remotely from the radiation detector array 300 via a connection 165. The connection 165 may be any type of wired or wireless connection. If the connection 165 is a wired connection, the connection 165 may include a slip ring electrical connection between any structure (e.g., gantry) supporting the radiation detector array 300 and a stationary support part of the support structure, which supports any part (e.g., a rotating ring). If the connection 165 is a wireless connection, the radiation detector array 300 may contain any suitable wireless transceiver to communicate data with another wireless transceiver that is in communication with the computing device 160. The computing device 160 may include processing and imaging applications that analyze each profile obtained by the radiation detector array 300, and a full set of profiles may be compiled to form a three-dimensional computed tomographic (CT) reconstruction of the object 10 and/or two-dimensional images of cross-sectional slices of the object 10.

Various alternatives to the design of the X-ray imaging system 100 of FIG. 1A may be employed to practice embodiments of the present disclosure. X-ray imaging systems may be designed in various architectures and configurations. For example, an X-ray imaging system may have a helical architecture. In a helical X-ray imaging scanner, the X-ray source 110 and radiation detector array 300 are attached to a freely rotating gantry. During a scan, the support structure (e.g., table) 105 moves the object 10 smoothly through the scanner, or alternatively, the X-ray source 110 and detector array 300 may move along the length of the object 10, creating helical path traced out by the X-ray beam. Alternatively, in an orbital X-ray imaging scanner, the object 10 may remain stationary while the gantry rotates completely or partially around the object 10 (e.g., to image a heart or a brain in one revolution). Slip rings may be used to transfer power and/or data on and off the rotating gantry. In other embodiments, the X-ray imaging system may be a tomosynthesis X-ray imaging system. In a tomosynthesis X-ray scanner, the gantry may move in a limited rotation angle (e.g., between 15 degrees and 60 degrees) in order to detect a cross-sectional slice of the object 10. The tomosynthesis X-ray scanner may be able to acquire slices at different depths and with different thicknesses that may be reconstructed via image processing. Alternatively, the X-Ray imaging system 100 may be a non-destructive testing system.

FIG. 1B illustrates components of an X-ray imaging system, including components within the ASIC 130 configured to count X-ray photons detected in each pixel detector 126 within a set of energy bins. As used herein, the terms “energy bin” and “bin” refer to a particular range of measured photon energies between a minimum energy threshold and a maximum energy threshold. For example, a first bin may refer to counts of photons determined to have an energy greater than a threshold energy (referred to as a trigger threshold, e.g., 20 keV) and less than 40 keV, while a second bin may refer to counts of photons determined to have an energy greater than 40 keV and less than 60 keV, and so forth.

X-rays 107 from an X-ray source (e.g., X-ray tube) 110 may be attenuated by a target (e.g., an object 10, such as a human or animal patient) before interacting with the radiation detector material within the pixelated detector array 300. An X-ray photon interacting (e.g., via the photoelectric effect) with a pixelated radiation detector material generates an electron cloud within the material that is swept by an electric field to the anode electrode 128. The charge gathered on the anode creates a signal that is integrated by a charge sensitive amplifier (CSA) 131. There may be a CSA 131 for each pixel detector 126 (e.g., for each anode 128) within the pixelated X-ray detector array 300. The voltage of the CSA output signal may be proportional to the energy of the X-ray photon. The output signal of the CSA may be processed by an analog filter or shaper 132.

The filtered output may be connected to the inputs of a number of analog comparators 134, with each comparator connected to a digital-to-analog converter (DAC) 133 that inputs to the comparator a DAC output voltage that corresponds to the threshold level defining the limits of an energy bin. The detector circuitry 130 may be configured so that after the CSA voltage has stabilized (after the dead time), that voltage may be between two voltage thresholds set by two DACs 133, which determines the output of the comparators 134. Outputs from the comparators 134 may be processed through decision gates 137, with a positive output from a comparator 134 corresponding to a particular energy bin (defined by the DAC output voltages) resulting in a count added to an associated counter 135 for the particular energy bin. Periodically, the counts in each energy bin counter 135 are output as signals 138 to the control unit 170.

Other suitable configurations for the read-out electronics of the ASIC 130 are within the contemplated scope of disclosure. For example, in some configurations, the analog voltage signals from the CSA may be converted to digital signals using an analog-to-digital converter (ADC) prior to being sorted into the respective energy bins.

The detector array 300 of an X-ray imaging system may include an array of radiation detector elements, referred to herein as pixel detectors. The signals from the pixel detectors may be processed by a pixel detector circuit (e.g., an above-described ASIC 130), which may sort detected photons into energy bins based on the energy of each photon or the voltage generated by the received photon. When an X-ray photon is detected, its energy is determined and the X-ray photon count for its associated energy bin is incremented. For example, if the detected energy of an X-ray photon is 24 kilo-electron-volts (keV), the X-ray photon count for the energy bin of 20-40 keV may be incremented. The number of energy bins may be three or more, such as four to twelve. In an illustrative example, an X-ray photon counting detector may have four energy bins: a first bin for detecting photons having an energy between 20 keV and 40 keV, a second bin for detecting photons having an energy between 40 keV and 60 keV, a third bin for detecting photons having an energy between 60 keV and 90 keV, and a fourth bin for detecting photons having an energy above 90 keV (e.g., between 90 keV and 120 keV). The greater the total number of energy bins, the better the material discrimination. The total number of energy bins and the energy range of each bin may be selectable by a user, such as by adjusting the threshold levels defining the limits of the respective energy bins in the read-out ASIC 130 as shown in FIG. 1B.

In various embodiments, a detector array 300 for an X-ray imaging system 100 as described above may include a plurality of pixel detectors 126 extending over a two-dimensional (2D) detector array surface. A typical radiation detector array 300 may include an array of individual radiation sensors 80 arranged side-by-side to provide the 2D detector array surface. The radiation sensors 80 may be located sufficiently close to each other to treat the 2D detector surface as essentially continuous, even though there are small gaps present between adjacent radiation sensors 80. Each radiation sensor 80 may comprise a semiconductor detector material plate 125, a continuous cathode electrode 122 located on a first side of the semiconductor detector material plate 125, and a plurality of anode electrodes 128 located on a second side of the semiconductor detector material plate 125. Each of the pixel detectors 126 comprises one the plurality of anode electrodes 128 and portions of the continuous cathode electrode 122 and the semiconductor detector material plate 125 overlying the one of the plurality of anode electrodes 128.

The detector array 300 (which is also referred herein as a detector module system (DMS)) may further include a modular configuration including a plurality of detector modules, where each detector module may include at least one above-described radiation sensor 80, at least one ASIC 130 (also known as a read-out integrated circuit (ROIC)) electrically coupled to the at least one radiation sensor 80, and a module circuit board. The module circuit board may support transmission of electrical power, control signals, and data signals between the module circuit board and the at least one ASIC 130 and the at least one radiation sensor 80 of the detector module, and may further support transmission of electrical power, control signals, and data signals between the module circuit board and the control unit 170 of the X-ray imaging system 100, other module circuit boards of the detector array, and/or a power supply for the detector array. A plurality of detector modules may be assembled on a common support structure, such as a detector array frame, to form a detector array 300.

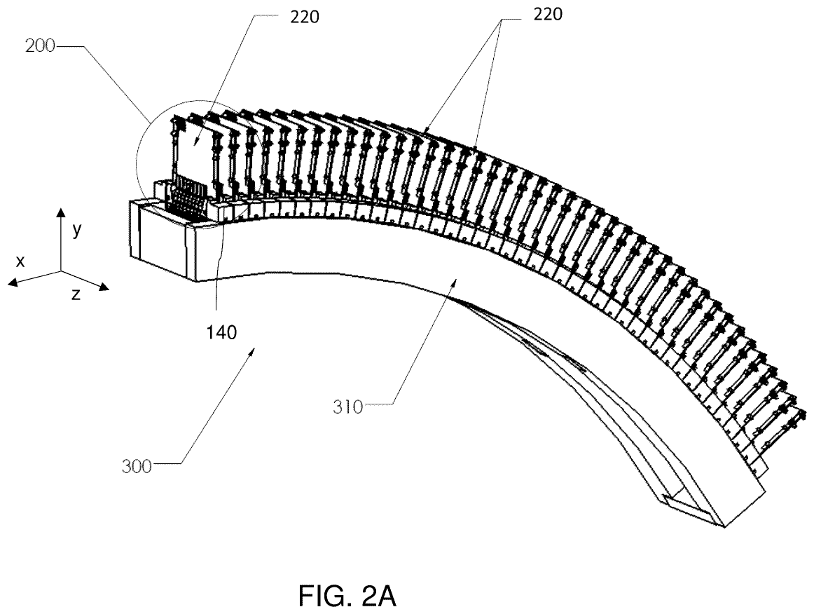

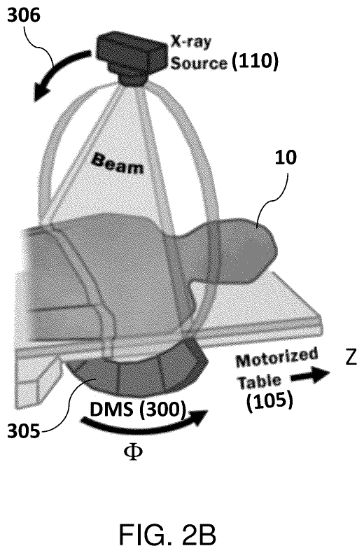

FIG. 2A is a rear perspective view of a detector array 300 for a computed tomography (CT) X-ray imaging system according to various embodiment of the present disclosure. The detector array 300 in this embodiment includes multiple detector modules 200 mounted on a detector array frame 310. The detector array frame 310 may be configured to provide attachment of a row of detector modules 200 such that physically exposed surfaces of the radiation sensors 80 of the detector modules 200 collectively form a curved detection surface located within a cylindrical surface. The multiple detector modules 200 may be assembled such that radiation sensors attached to neighboring detector modules 200 abut each other, i.e., make direct surface contact with each other and/or include a gap between adjacent radiation sensors that is less than 3 mm, and/or less than 2 mm, and/or less than 1 mm in the x-direction. In some embodiments, the detector modules 200 may be mounted to the detector array frame 310 by attaching frame bars 140 of the detector modules 200 to the detector array frame 310 using suitable mechanical fasteners. The radiation sensors and ASICs 130 of each module 200 may be mounted over a first (i.e., front) surface of the frame bar 140. Each module 200 may also include a module circuit board 220 extending away from a rear surface of the frame bar 140. Major surfaces of the module circuit boards 220 of the detector modules 200 may face each other in the detector array 300.

FIG. 2B is a perspective view of a CT X-ray imaging system 100 illustrating the orientation of the detector array 300 with respect to an X-ray source 110 and an object (e.g., patient) 10 being imaged according to various embodiments of the present disclosure. Referring to FIG. 2B, the X-ray source 110 and the detector array 300 (e.g., DMS) may rotate around the object 10 and the support structure (e.g., motorized table) 105 along the direction of arrow 306 to obtain cross-sectional image profiles (or “slices”) of the object 10. The X-ray source 110 and the detector array 300 may also be translated relative to the object 10 (e.g., by moving the support structure 105 and the object 10 with respect to the X-ray source 110 and the detector array 300 and/or by moving the X-ray source 110 and the detector array 300 along the length of the object 10) along a horizontal direction to obtain cross-sectional image “slices” of different portions of the object 10. The direction of the horizontal movement of the X-ray source 110 and the detector array 300 relative to the object 10 may be referred to as the “Z-axis” direction, which may be parallel to the axis of rotation of the X-ray source 110 and the detector array 300 around the object 10. As discussed above, the detector array 300 may also have a curved shape along the direction in which the X-ray source 110 and the detector array 300 rotate around the object 10. The pixel detectors 126 of the detector array 300 may be arranged in multiple columns and rows of pixel detectors, where each column may extend along the Z-axis direction, and each row may extend along the direction of rotation 306 (e.g., angular Φ direction) of the detector array 300 around the object 10. Accordingly, the location of each pixel detector 126 within the detector array 300 may be defined by a unique row and column pair, where the location of the pixel detector 126 within a given column may be defined by its location along the Z-axis direction, and the location of the pixel detector within a given row may be defined by the azimuth angle Φ of a line segment extending between the pixel detector 126 and the focal spot of the X-ray source 110, where all pixel detectors 126 within the same column may have the same azimuth angle Φ. The detector array 300 shown in FIG. 2B may be similar to the detector array 300 described above with reference to FIG. 2A. The detector array 300 may further include a suitable housing or enclosure 305 that encloses and protects the module circuit boards 220.

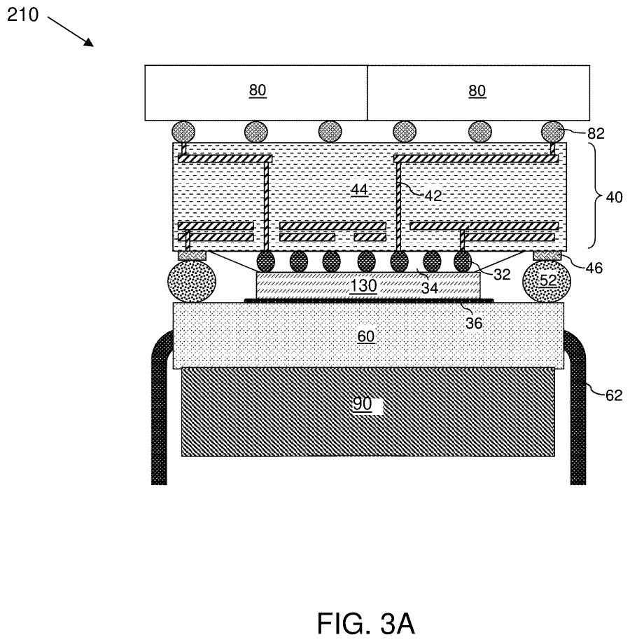

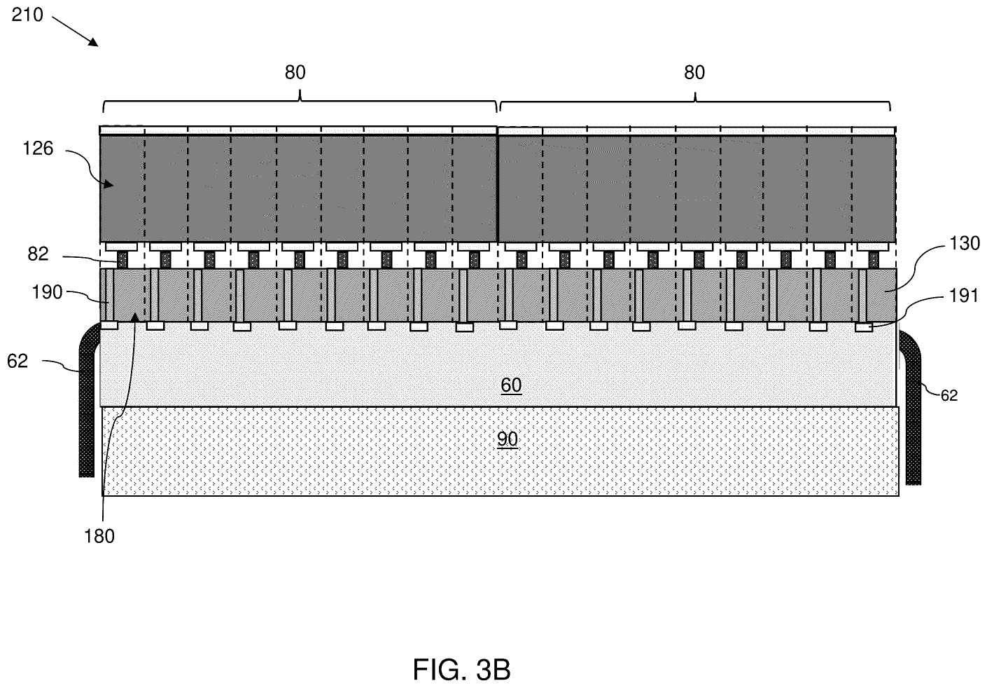

In some embodiments, each of the detector modules 200 of the detector array 300, such as the detector array 300 shown in FIGS. 2A and 2B may be constructed from a set of radiation detector units, which may also be referred to as “mini-modules” or “submodules.” In some embodiments, each of the radiation detector units may include one or more radiation sensors 80 coupled to a single ASIC 130. FIG. 3A is a vertical cross-sectional view of a radiation detector unit 210 according to one embodiment of the present disclosure. Referring to FIG. 3A, the radiation detector unit 210 includes a pair of above-described radiation sensors 80, an ASIC 130, and an interposer 40 disposed between the radiation sensors 80 and the ASIC 130. The interposer 40 includes an insulating interposer matrix 44, which may include semiconductor, glass, polymer (e.g., printed circuit board insulating laminate) or ceramic material, and a plurality of metal interconnect structures 42 embedded within the insulating interposer matrix 44. Bonding pads (not expressly shown) may be located on the front side and the backside of the interposer 40 and may be electrically coupled to the metal interconnect structures 42. As used herein, the “front side” of elements refers to the side that faces the incoming radiation, and the “backside” of elements refers to the side that is the opposite side of the front side.

The ASIC 130 may interface with external components through bonding pads that are located on the front side of the ASIC 130. The bonding pads may include input pads, output pads, and power pad. The bonding pad(s) of the ASIC 130 can be arranged as an array, such as a rectangular array. At least a portion of the bonding pads on the backside of the interposer 40 may have the same periodicity as the bonding pads on the front side of the ASIC 130.

Each of the radiation sensors 80 may have bonding pads located on the backside of the radiation sensor 80. The bonding pads on the backside of the radiation sensors 80 may be arranged as an array, such as a rectangular array. The front side bonding pads of the interposer 40 may have the same periodicity as the periodicity of bonding pads on the backside of the radiation sensors 80.

Referring again to FIG. 3A, the ASIC 130 may be mounted to the backside of the interposer 40 through an array of first bonding structures 32, such as solder balls or copper pillars. Specifically, the array of first bonding structures 32, may be bonded to a respective pair of a bonding pads on the front side of the ASIC 20 and a backside bonding pad of the interposer 40 employing a flip-chip bonding process (e.g., a C4 bonding process and/or a thermo-compression process in embodiments using copper pillar bonding structures). An insulating matrix 34 may be formed around the array of first bonding structures 32 to structurally reinforce the array of first bonding structures 32. While a configuration in which one ASIC 130 is bonded to the backside of the interposer 40 is illustrated herein, two or more ASICs 130 may be bonded to the backside of the interposer 40 in some embodiments. At least one radiation sensor 80 may be bonded to the front side of the interposer 40 via bonding material portions 82. In some embodiments, the bonding material portions 82 may include a low temperature solder material or conductive epoxy. In one embodiment, the at least one radiation sensor 80 includes a pair of radiation sensors 80 having a respective rectangular shape and adjoined to each other with no gap or with a gap less than 3 mm, and/or less than 2 mm, and/or less than 1 mm. X-ray photon detection signals from the radiation sensors 80 may be transmitted to the ASIC 130 via the interposer 40. The ASIC 130 may be configured to convert event detection signals from the at least one radiation sensor 80 to digital detection signals, which can include the pixel location and the energy range of the detected radiation.

The radiation detector unit 210 may further include a carrier board 60 and at least one flex cable assembly 62, which are configured to route power supply to the ASIC 130 and to the at least one radiation sensor 80, control signals to the ASIC 130, and data signals (e.g., digital detection signals) generated by the ASIC 130 and transmitted through the interposer 40. One end of each flex cable assembly 62 may be attached to a respective side of the carrier board 60, and another end of each flex cable assembly may be connected to a module circuit board 220 as shown in FIG. 2. The carrier board 60 may be a printed circuit board including an insulating substrate and printed interconnection circuits. A thermally conductive paste 36, such as a silver paste layer, may be provided between the backside of the ASIC 130 and the front side of the carrier board 60. An array of second solder balls 52 may each be bonded to a bonding pad 46 on the backside of the interposer 40 and a corresponding bonding pad (not expressly shown in FIG. 3A) on the front side of the carrier board 60. The second solder balls 52 may be located around and laterally spaced away from peripheral side surfaces of the ASIC 130. Each flex cable assembly 62 may include signal wires and power wires. The signal wires are configured to transmit the electronic detection signals and control signals, and the power wires are configured to provide electrical power to the interposer 40, which distributes the electrical power to the ASIC 130 and the radiation sensor(s) 80. In some embodiments, the flex cable assembly 62 can be more flexible (i.e., can bend with a lower application of force) than the carrier board 60.

The radiation sensors 80, the interposer 40, the ASIC 130 and the carrier board 60 may be mounted to a supporting substrate (e.g., a block) 90 as shown in FIG. 3A. The supporting substrate may include a high thermal conductivity material such as a metal (e.g., aluminum, copper, etc.). The supporting substrate 90 may function as a heat sink for the radiation detector unit 210. The supporting substrate 90 may be attached to the backside of the carrier board 60 using a thermally conductive adhesive such as a thermally conductive paste, and/or by mechanical connection structures (such as snap-in connectors, screws, and/or bolts and nuts).

FIG. 3B is a vertical cross-section view of an alternative configuration of a radiation detector unit 210 according to an alternative embodiment of the present disclosure. In this embodiment, a pair of radiation sensors 80 is directly mounted to an ASIC 130 via a plurality of bonding material portions 82. Referring to FIG. 3B, each radiation sensor 80 may include an above-described detector material 125 having at least one cathode electrode 122 on a front side of the radiation sensor 80 and a plurality of anode electrodes 128 on a back side of the radiation sensor 80 defining an array of pixel detectors 126 as described above. Each radiation sensor 80 may be directly mounted to the front side of the ASIC 130 via a plurality of bonding material portions 82. In other words, each radiation sensor 80 may be mechanically and electrically coupled to the ASIC 130 via the plurality of bonding material portions 82, and no interposer 40 or similar intervening structural component for routing of electrical signals between the radiation sensors 80 and the ASIC 130 is located between the back side of each of the radiation sensors 80 and the front side of the ASIC 130. Such a configuration may be referred to as a “direct attach” radiation detector unit 210. Exemplary embodiments of “direct attach” radiation detector units 210 and detector modules 200 are described, for example, in U.S. Provisional Patent Application No. 63/380,769, filed on Oct. 25, 2022, and U.S. patent application Ser. No. 18/158,695, filed on Jan. 24, 2023, the entire teachings of both of which are incorporated by reference herein for all purposes.

The plurality of bonding material portions 82 may be arranged in an array, such as a rectangular array, having the same periodicity as the periodicity of the anode electrodes 128 on the back sides of the radiation sensors 80. Thus, each bonding material portion 82 may electrically couple a respective anode electrode 128 of a radiation sensor 80 to the front side of the ASIC 130. In one non-limiting embodiment, the bonding material portions 82 may be composed of a conductive epoxy. Other suitable bonding materials, such as a low temperature solder material with under bump metallization, may be utilized to mount the radiation sensor 80 to the front side of the ASIC 130. An optional underfill material (not shown in FIG. 3B) may be provided in the space between the back side surface of the radiation sensors 80 and the front side surface of the ASIC 130 and laterally surrounding the bonding material portions 82. The underfill material may include a suitable insulating material, such as an insulating epoxy material.

In the embodiment illustrated in FIG. 3B, a pair of radiation sensors 80 are mounted to the front side of the ASIC 130, although it will be understood that in other embodiments, a single radiation sensor 80 or more than two radiation sensors 80 may be mounted to the front side of the ASIC 130. In some embodiments, the horizontal dimensions of the ASIC 130 may be substantially equal to the combined dimensions of the one or more radiation sensors 80 mounted thereto along the corresponding horizontal directions. Thus, each pixel detector 126 of the radiation sensor(s) 80 may overlie a corresponding pixel region 180 of the ASIC 130. In some embodiments, the ASIC 130 and each of the radiation sensors 80 mounted thereto may have a rectangular periphery. This may enable any of the four peripheral sides of the radiation detector unit 210 to be abutted against a peripheral side of an adjacent radiation detector unit 210 upon assembly of multiple radiation detector units 210 in a detector array 300.

The radiation detector unit 210 of FIG. 3B may further include a carrier board 60 that is configured to route power supply to the ASIC 130 and to the at least one radiation sensor 80, control signals to the ASIC 130, and data signals (e.g., digital detection signals) generated by the ASIC 130. One or more cables 62, such as a flex cable assembly, may be attached to a respective side of the carrier board 60, and another end of each cable may be connected to the above-described module circuit board 220. The carrier board 60 may be a printed circuit board including an insulating substrate and printed interconnection circuits. In various embodiments, the ASIC 130 may be disposed over the carrier board 60 such that the back side of the ASIC 130 may contact the front side of the carrier board 60.

Optionally, a plurality of through-substrate vias (TSVs) 190 may be provided in the ASIC 130. The TSVs 190 may include an electrically conductive material (e.g., a metal material, such as copper) that extends between the front side and the back side of the ASIC 130. In embodiments in which the ASIC 130 may be formed on and/or in a silicon substrate, the TSVs 190 may also be referred to as “through-silicon vias.”

Accordingly, electrical connections between the carrier board 60 and the ASIC 130 may be made through the back side of the ASIC 130 via the plurality of TSVs 190. In particular, each of the TSVs 190 may electrically contact a conductive trace 191 located on the front side of the carrier board 60, as schematically illustrated in FIG. 3B. This may obviate the need for wire bond and/or interposer connections between the front side of the carrier board 60 and the front side of the ASIC 130, which may help to minimize the footprint of the radiation detector unit 210. In various embodiments, outer periphery of the carrier board 60 may not extend beyond the outer periphery of the ASIC(s) 130 and radiation sensor(s) 80 located over the carrier board 60 so as to provide a radiation detector unit 210 that is buttable on all four sides.

In other embodiments, a portion of the ASIC 130 may extend beyond the outer periphery of the radiation sensor(s) 80 and a portion of the carrier board 60 may extend beyond the outer periphery of the ASIC 130. A plurality of wire bond connections may extend between the front side of the carrier board 60 and the front side of the ASIC 130, as is described and illustrated in the above-referenced U.S. patent application Ser. No. 18/158,695. The wire bond connections between the carrier board 60 and the ASIC 130 may be in addition to, or may be in lieu of, electrical connections between the front side of the carrier board 60 and the back side of the ASIC 130 via TSVs 190 as described above.

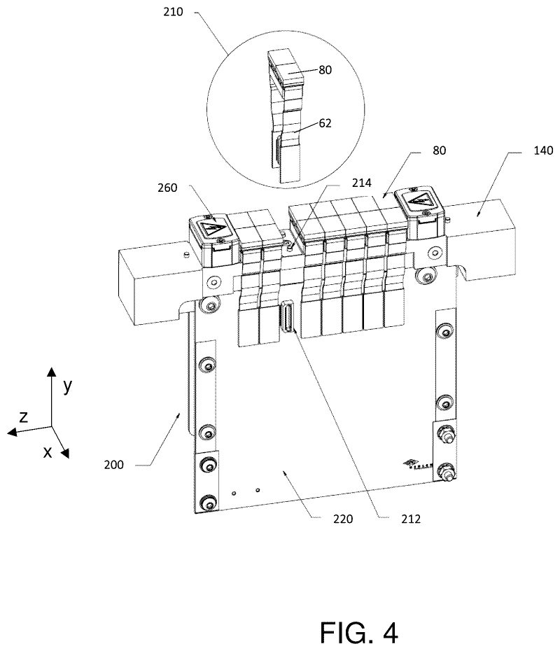

FIG. 4 is a perspective view of a detector module 200 including a plurality of above-described radiation detector units 210 mounted to an above-described frame bar 140. A column of radiation detector units 210 may be mounted to the front side of the frame bar 140. Engagement features 214 may optionally be provided on the front side of the frame bar 140 that may made with corresponding engagement features (not shown) on the backside of the supporting substrate (e.g., carrier board 60) of each of the radiation detector units 210. End holders 260 may optionally be located at either end of the column of radiation detector units 210. A module circuit board 220 may be mechanically coupled to the frame bar 140 by suitable mechanical fastener(s). Each radiation detector unit 210 of the detector module may be electrically coupled to the module circuit board 220 by a flex cable assembly 62. In the embodiment shown in FIG. 4, the module circuit board 220 may include board-side connectors 212, where each board-side connector 212 may be connected to a connector, such as a snap-in connector 66, of a respective flex cable. In the embodiment shown in FIG. 4, each detector module 200 includes a column of eight (8) radiation detector units 210, each including a pair of radiation sensors 80 mounted over an ASIC 130. It will be understood that other configurations for the detector modules 200 are within the scope of this disclosure.

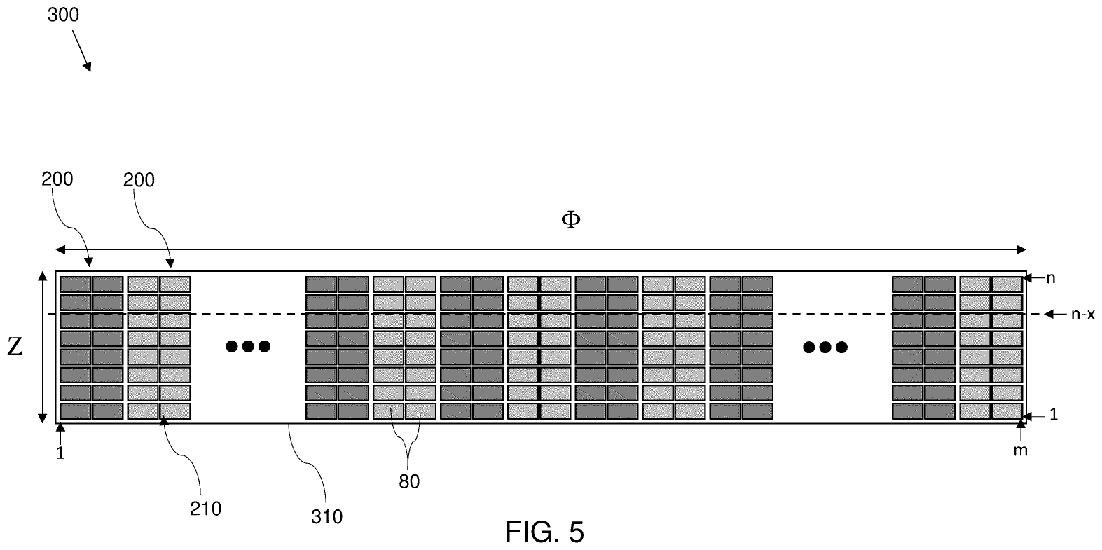

FIG. 5 is a top view of a detector array 300 including a plurality of detector modules 210 according to comparative embodiments of the present disclosure. Referring to FIG. 5, the detector array 300 may include a plurality of above-described detector modules 200 mounted on a detector array frame 310 to provide a continuous detector surface. For clarity of illustration, adjacent detector modules 200 are depicted in alternating shading in FIG. 5. The detector surface may include an m×n array of pixel detectors 126 including n rows of pixel detectors 126 extending along the Φ direction and m columns of pixel detectors 126 extending along the Z-axis direction, where m and n are integers.

Each detector module 200 of the detector array 300 may include a plurality of radiation detector units 210 mounted on a common support. In the embodiment shown in FIG. 5, each module includes a column of eight (8) radiation detector units 210 extending along the Z-axis dimension, where each radiation detector unit 210 includes a pair of radiation sensors 80 located adjacent to one another along the Φ direction and mounted over a common ASIC 130. Other suitable configurations for the detector modules 200 and/or radiation detector units 210 of the detector array 300 may also be utilized.

The detector modules 200 and radiation detector units 210 of a detector array 300 as shown in FIG. 5 may have a precise alignment such that the edges of each of the radiation sensors 80 may be aligned in a grid configuration along both the Φ and Z-axis directions. Such a configuration may facilitate the use of an anti-scatter grid (ASG) over the front surface of the detector array 300. However, the present inventors have discovered that such a configuration of a modular detector array 300 may not be ideal in terms of image quality. This is because the pixel detectors 126 along the peripheral edges of radiation sensors 80 tend to exhibit relatively poorer performance than the pixel detectors 126 located in the interior regions of the radiation sensors 80. This may be due to imperfect passivation or lack of passivation along the exposed semiconductor crystal walls and/or damage incurred during the wafer dicing process, among other factors. The presence of these edge pixel detectors may be particularly problematic for CT reconstruction because the image data is typically processed in “slices,” meaning that image data from each row of pixel detectors 126 located at the same position along the Z-axis direction may be processed together. Because the edge pixel detectors 126 in the detector array 300 shown in FIG. 5 are all aligned, this means that a number of rows in the detector array 300 are composed entirely of edge pixel detectors 126. One such edge pixel detector 126 row, n-x, where x is an integer less than n, is shown in FIG. 5. In the detector array 500 shown in FIG. 5, for example, sixteen (16) of the n rows of pixel detectors 126 are edge pixel detector rows made up entirely of relatively poor performing edge pixel detectors 126. Moreover, many of these edge pixel detector rows occur consecutively along the Z-axis direction between adjacent rows of radiation detector units 210, which may further negatively affect image quality.

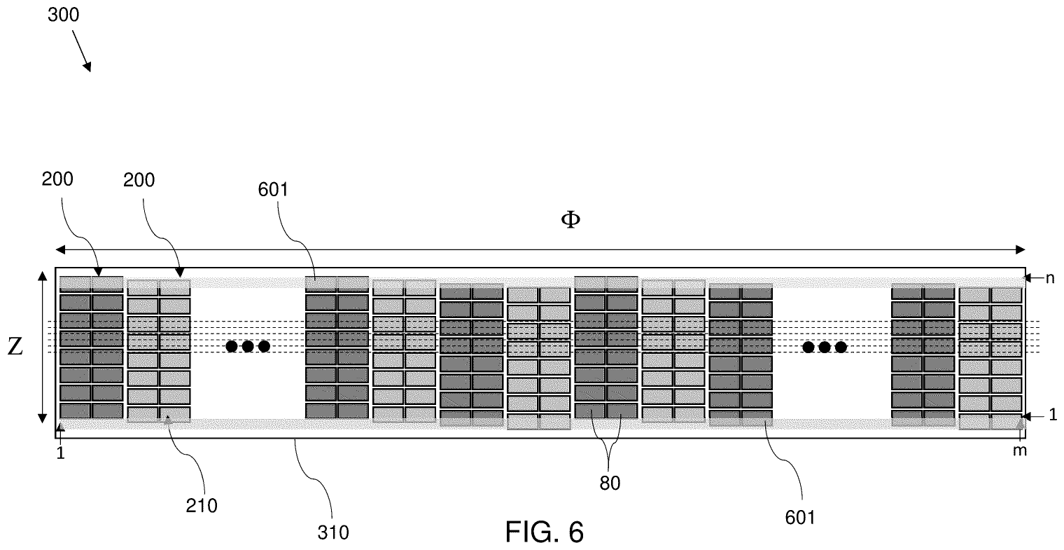

Various embodiments include detector arrays 300 in which the detector modules 200 have a staggered or offset configuration along the Z-axis direction. FIG. 6 is a top view of a detector array 300 including a plurality of detector modules 200 that are staggered along the Z-axis direction according to various embodiments of the present disclosure. For clarity of illustration, adjacent detector modules 200 are depicted in alternating shading in FIG. 6.

Referring to FIG. 6, adjacent detector modules 200 may be offset relative to one another by an integer number of pixel detectors 126. That is, pixel detectors 126 in the xth row of pixel detectors 126 in a first detector module 200 may be aligned with pixel detectors 126 in the x±ith row of pixel detectors 126 in the adjacent detector module 200, where i is an integer value and x is an integer less than n. Accordingly, the edge pixel detectors 126 may be distributed across different rows of the detector module 300, and no rows of the detector module 300 may be composed exclusively of edge pixel detectors 126 (i.e., there are no edge pixel detector rows). By distributing the poorer performing edge pixel detectors 126 across different rows such that they are not concentrated within the same “slices,” the overall image quality obtained by the detector array 300 may be improved. In addition, because the pixel detectors 126 of the detector array 300 may be arranged in a rectangular grid, this may facilitate the use of an anti-scatter grid (ASG) over the front side of the detector array 300.

FIG. 6 illustrates several rows of pixel detectors 126 by dashed lines. In some embodiments, the detector modules 200 may be staggered along the Z-axis direction such that each row of pixel detectors 126 extending along the Φ direction may include some edge pixel detectors 126 and some interior pixel detectors 126. Alternatively, the detector modules 200 may be staggered such that some of the rows include a mix of edge pixel detectors 126 and interior pixel detectors 126, and the remaining rows may not include any of the edge pixel detectors 126 extending along the Φ direction (i.e., along the top and bottom peripheral edges of the radiation sensors 80). By providing a staggered configuration of the radiation sensors 80, poorer performing pixel detectors 126 along the edges of the radiation sensors 80 may be distributed across different rows and overall image quality may be improved.

The detector modules 200 in the embodiment of FIG. 6 may have identical sizes and shapes. Accordingly, the peripheral edges of the detector surface along the Φ direction may have an irregular, stepped shape due to the staggering of the detector modules 200 as shown in FIG. 6. Depending on the particular arrangement of the detector modules 200 within the detector array 300, some of the pixel detectors 126 in the array 300 may not be useable for CT image reconstruction. This is because pixel detectors 126 located adjacent the stepped peripheral edges of the detector surface may not form complete rows pixel detectors 126 along the Φ direction. Thus, a complete image data set may not be obtained along these “slices.”

FIG. 6 illustrates these non-usable pixel detectors 126 by the shaded areas 601 along the top and bottom regions of the detector array 300. As shown in FIG. 6, the rows of pixel detectors 126 within the shaded areas 601 along the top and bottom are not continuous across the entire length of the detector surface along the Φ direction because the staggered configuration of the detector modules 200 results in gaps in the detector surface along the Φ direction. In contrast, the rows of pixel detectors 126 within the central portion of the detector surface are continuous because they extend continuously across the full length of the detector surface along the <D direction. Accordingly, there may be a tradeoff in terms of the length along the Z-axis direction that may be scanned during a single rotation of the X-ray source 110 and the detector array 300. In some embodiments, all or a portion of the pixel detectors 126 within the shaded areas 601 may be used for other purposes, such as for calibration and/or for auxiliary/monitoring functions during scans of the object 10. In these embodiments, the ASG is also extended to add extra rows in the shaded areas 601 to match the Z-axis direction shift of the pixel detectors 126. Alternatively or in addition, some or all of the pixel detectors 126 within the shaded areas 601 may be powered down (i.e., receive no electric power) to minimize power dissipation. This may include, for example, powering down the channel circuitry within the ASIC 130 that is used to output image data for the unused pixel detectors 126.

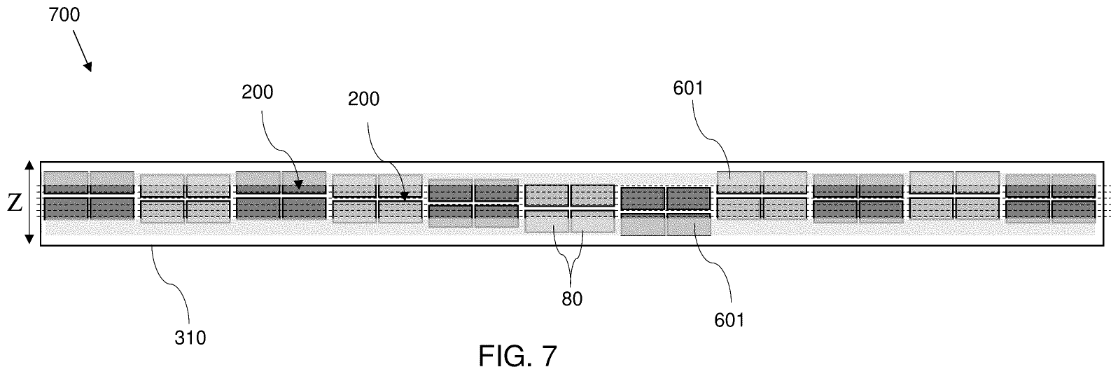

FIG. 7 is a top view of an alternative configuration of a detector array 700 including a plurality of detector modules 200 that are staggered along the Z-axis direction according to various embodiments of the present disclosure. For clarity of illustration, adjacent detector modules 200 are depicted in alternating shading in FIG. 7. The detector array 700 shown in FIG. 7 may have a reduced length along the Z-axis dimension as compared to the detector array 300 described above with reference to FIG. 6. In this example, each detector module 200 may include a 2×2 array of radiation sensors 80. A detector array 700 having a reduced Z-axis length as shown in FIG. 7 may be used, for example, in non-destructive testing applications. As in the embodiment described above with reference to FIG. 6, the adjacent detector modules 200 are offset relative to one another by an integer number of pixel detectors 126. In some embodiments, the adjacent detector modules 200 may be offset by a single pixel. Several rows of pixel detectors 126 are indicated by dashed lines in FIG. 7. Pixel detectors in the shaded regions 601 may not be useable for imaging, and may be used for other purposes (e.g., calibration, auxiliary/monitoring functions, etc.) or may be powered down to minimize power dissipation.

The devices of the embodiments of the present disclosure can be employed in various radiation detection systems including computed tomography (CT) imaging systems. Any direct conversion radiation sensors may be employed such as radiation sensors employing Si, Ge, GaAs, CdTe, CdZnTe, and/or other similar semiconductor materials.

The radiation detectors of the present embodiments may be used for medical imaging as radiation detectors in High-Flux applications as in X-ray Computed Tomography (CT) for medical applications, and for non-medical imaging applications, such as in baggage security scanning and industrial inspection applications.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

1. A detector array, comprising:
a plurality of radiation sensors each comprising a two dimensional array of pixel detectors, wherein:
the plurality of radiation sensors are arranged in rows of pixel detectors extending in a first direction and columns of pixel detectors extending in a second direction; and
at least some of the plurality of the radiation sensors that are located adjacent to one another along the first direction are offset from one another along the second direction by an integer number of pixel detectors.

2. The detector array of claim 1, wherein the edge pixel detectors of the respective radiation sensors extending along the first direction are located in different rows of the pixel detectors.

3. The detector array of claim 2, wherein each of the rows of the pixel detectors includes at least some of the edge pixel detectors extending along the first direction and at least some interior pixel detectors.

4. The detector array of claim 2, wherein:
a first set of the rows of the pixel detectors include at least some of the edge pixel detectors extending along the first direction and at least some interior pixel detectors; and
a second set of the rows of pixel detectors do not include any of the edge pixel detectors extending along the first direction.

5. The detector array of claim 1, wherein:
each radiation sensor of the plurality of radiation sensors has a same size and shape;
each radiation sensor of the plurality of radiation sensors comprises a semiconductor detector material plate, a continuous cathode located on a first side of the semiconductor detector material plate, and a plurality of anodes located on a second side of the semiconductor detector material plate; and
each of the pixel detectors comprises one the plurality of anodes and portions of the continuous cathode and the semiconductor detector material plate overlying the one of the plurality of anodes.

6. The detector array of claim 5, wherein the detector array comprises a plurality of detector modules located adjacent to one another along the first direction, wherein each detector module comprises a column of radiation sensors located adjacent to one another along the second direction, and each detector module is offset from an adjacent detector module along the second direction.

7. The detector array of claim 6, wherein each of the plurality of the detector modules comprises multiple columns of radiation sensors located adjacent to one another along the first direction.

8. The detector array of claim 6, wherein each of the plurality of the detector modules further comprises at least one application specific integrated circuit (ASIC) coupled to one or more of the plurality of the radiation sensors.

9. The detector array of claim 1, wherein the detector array comprises an energy discriminating photon counting radiation detector array.

10. The detector array of claim 1, wherein the plurality of radiation sensors are arranged in an abutting configuration to provide a detector surface.

11. The detector array of claim 10, wherein the detector surface has an angled or tilted surface along the first direction.

12. The detector array of claim 10, wherein peripheral edges of the detector surface extending along the first direction have a stepped shape.

13. The detector array of claim 12, wherein the pixel detectors located adjacent to the peripheral edges of the detector surface extending along the first direction are not used for imaging during operation of the detector array.

14. The detector array of claim 13, wherein the pixel detectors located adjacent to the peripheral edges of the detector surface extending along the first direction are configured to be used for calibration, auxiliary function, or monitoring function during the operation of the detector array.

15. The detector array of claim 13, wherein the pixel detectors located adjacent to the peripheral edges of the detector surface extending along the first direction are powered down during the operation of the detector array.

16. An X-ray imaging system, comprising:
a radiation source configured to emit an X-ray beam; and
the detector array of claim 1 that is configured to receive the X-ray beam from the radiation source through an intervening space configured to contain an object therein.

17. The X-ray imaging system of claim 16, wherein the X-ray imaging system comprises a photon-counting computerized tomography (PCCT) imaging system comprising an image reconstruction system configured to run an automated image reconstruction algorithm on event detection signals generated by the pixel detectors of the detector array.

18. The X-ray imaging system of claim 16, wherein the X-ray imaging system comprises a non-destructive testing or inspection system.

19. An X-ray imaging method, comprising:
passing an X-ray beam through an object to the radiation detector of claim 12; and
generating an image based signals received from the radiation detector.

20. The X-ray imaging method of claim 19, wherein the pixel detectors located adjacent to the peripheral edges of the detector surface extending along the first direction are not used for generating the image, and are either used for calibration, auxiliary function, or monitoring function or are powered down while the X-ray beam is passed through the object.
